(19) United States
(12) Patent Application Publication
(10) Pub. No.: US 2026/0282374 A1
(43) Pub. Date: Sep. 17, 2026

(54) SEMICONDUCTOR DEVICE, FORMING METHOD, MEMORY DEVICE, AND SEMICONDUCTOR STRUCTURE

(71) Applicant: Yangtze Memory Technologies Holding Co., Ltd., Wuhan (CN)

(72) Inventors: Tao YANG, Wuhan (CN); Yuxuan FANG, Wuhan (CN); Hao ZHENG, Wuhan (CN); Zhiliang XIA, Wuhan (CN); Zongliang HUO, Wuhan (CN)

(21) Appl. No.: 19/421,526

(22) Filed: Dec. 16, 2025

(30) Foreign Application Priority Data
Mar. 17, 2025 (CN) 202510315294.5

(51) Int. Cl. H10B 51/20; H10B 51/10; H10B 51/30

(52) U.S. Cl. CPC H10B 51/20; H10B 51/10; H10B 51/30

(57) ABSTRACT

Semiconductor devices, memory devices, systems, and forming methods are provided. In one aspect, a semiconductor device includes: n layers of semiconductor structures, memory structures arranged in an array, and first contact structures. The n layers of semiconductor structures are stacked along a first direction. Each layer of the n layers of semiconductor structure includes a first conductive layer and a second conductive layer that are spaced apart from each other. The first conductive layer is connected to a first end of one or more corresponding memory structures, and the second conductive layer is connected to a second end of the one or more corresponding memory structures. A first contact structure of the first contact structures extends through at least two layers of the n layers of semiconductor structures along the first direction, and is connected to at least two first conductive layers of the at least two layers.

### CROSS-REFERENCE TO RELATED APPLICATIONS

This application claims priority to Chinese Patent Application No. 202510315294.5, filed on Mar. 17, 2025, which is hereby incorporated by reference in its entirety.

### TECHNICAL FIELD

The present disclosure relates to, but is not limited to, a semiconductor device, a forming method, a memory device, and a semiconductor structure.

### BACKGROUND

As a new type of non-volatile memory technology, AND memory exhibits significant advantages in memory density and read/write speed due to its unique array structure and charge trapping mechanism, making it suitable as a computing-in-memory chip. The computing-in-memory chip can significantly reduce data migration overhead and become a key technical direction for breaking through the “memory wall” problem by embedding computing logic into memory cell and directly completing operation at data storage position.

### SUMMARY

Implementations of the present disclosure provide semiconductor devices, forming methods, memory devices, systems and semiconductor structures.

One aspect of the present disclosure features a semiconductor device, including: n layers of semiconductor structures, where n is an integer greater than 1; memory structures arranged in an array; and first contact structures. The n layers of semiconductor structures are stacked along a first direction, and each layer of the n layers of semiconductor structures includes a first conductive layer and a second conductive layer that are spaced apart from each other, the first conductive layer being connected to a first end of one or more memory structures of the memory structures, the second conductive layer being connected to a second end of the one or more memory structures of the memory structures. A first contact structure of the first contact structures extends through at least two layers of the n layers of semiconductor structures along the first direction, and a conductive structure in the first contact structure is connected to at least two first conductive layers of the at least two layers.

In some implementations, the semiconductor device further includes second contact structures. A second contact structure of the second contact structures extends through at least one layer of the n layers of semiconductor structures along the first direction, and the second contact structure is connected to a corresponding second conductive layer of the at least one layer.

In some implementations, the first contact structure is disposed on a side of the first conductive layer or at an end of the first conductive layer, and the second contact structure is disposed on a side of the second conductive layer or at an end of the second conductive layer.

In some implementations, the first contact structure is disposed between two corresponding memory structures of the memory structures, and the second contact structure is disposed at a periphery of the memory structures.

In some implementations, the first conductive layer is a source line layer, and the second conductive layer is a bit line layer, or the first conductive layer is a bit line layer, and the second conductive layer is a source line layer.

In some implementations, the source line layer is located on a side of two rows of the memory structures away from each other, a first portion of the bit line layer is located on a side of the two rows of the memory structures facing each other, and is connected to a second end of the one or more corresponding memory structures, and corresponding memory structures connected to the source line layer are correspondingly connected to two bit line layers, respectively.

In some implementations, a second portion of the bit line layer is located on a side of two rows of second contact structures away from each other, and is connected to the two rows of second contact structures, a third portion of the bit line layer connects the first portion and the second portion of the bit line layer, and a gap of the first portion of the bit line layer is smaller than that of the second portion of the bit line layer.

In some implementations, the source line layer includes a conductive portion and an insulating portion, and the conductive portion and the insulating portion are respectively located on two sides of a first contact structure corresponding to the source line layer.

In some implementations, the semiconductor device further includes a third contact structure. The third contact structure and a storage layer of a corresponding memory structure of the memory structures extend through the n layers of semiconductor structures along the first direction, the storage layer of the corresponding memory structure surrounds a sidewall of the third contact structure, and the third contact structure is connected to a corresponding word line layer. An outer sidewall of the storage layer is covered with an isolation layer of the corresponding memory structure, and a channel layer of the corresponding memory structure is at an intersection of the isolation layer and a respective one of the n layers of semiconductor structures.

In some implementations, the first contact structure includes a conductive structure and an insulating layer, and the insulating layer surrounds a sidewall of the conductive structure.

Another aspect of the present disclosure features a method of forming a semiconductor device, including: providing n layers of semiconductor structures stacked along a first direction, where n is an integer greater than 1, where each layer of the n layers of semiconductor structures includes a first conductive layer and a second conductive layer that are spaced apart from each other, the first conductive layer is connected to a first end of one or more memory structures, and the second conductive layer is connected to a second end of the one or more memory structures; and forming m first contact structures, where m is an integer smaller than n and greater than or equal to 1, where a first contact structure of the m first contact structures extends through at least two layers of the n layers of semiconductor structures along the first direction, and a conductive structure in the first contact structure is connected to at least two first conductive layers of the at least two layers.

In some implementations, forming the m first contact structures includes: etching a sacrificial layer and an insulating portion of the first conductive layer at a position close to a conductive portion of the first conductive layer to form m first vias, where a depth difference between adjacent two of the m first vias is greater than or equal to a thickness of two layers of the n layers of semiconductor structures; forming an insulating layer on an inner wall of each first via of the m first vias, where the insulating layer in the first via exposes insulating portions of at least two corresponding first conductive layers located at a bottom of the first via; etching the insulating portions of the at least two corresponding first conductive layers exposed in each of the first vias, until conductive portions of the at least two corresponding first conductive layers are exposed; and filling a respective conductive structure in each of the first vias to form the m first contact structures.

In some implementations, the method further includes: forming n second contact structures at a position close to a conductive portion of the second conductive layer, where each second contact structure of the n second contact structures extends through at least one layer of the n layers of semiconductor structures along the first direction, and is connected to a corresponding second conductive layer.

In some implementations, the first conductive layer is a source line layer, and the second conductive layer is a bit line layer, or the first conductive layer is a bit line layer, and the second conductive layer is a source line layer.

Another aspect of the present disclosure features a system, including: a memory device including a memory array and a peripheral circuit; and a processing circuit coupled to the memory device and configured to control the memory device. The memory array includes n layers of semiconductor structures, memory structures arranged in an array, and first contact structures, where n is an integer greater than 1, and the n layers of semiconductor structures are stacked along a first direction. Each layer of the n layers of semiconductor structures includes a first conductive layer and a second conductive layer that are spaced apart from each other, the first conductive layer being connected to a first end of one or more memory structures of the memory structures, the second conductive layer being connected to a second end of the one or more memory structures of the memory structures, and a first contact structure of the first contact structures extends through at least two layers of the n layers of semiconductor structures along the first direction, and is connected to at least two first conductive layers of the at least two layers.

In some implementations, the system includes a computing-in-memory chip, and the processing circuit is configured to receive data from the memory device and perform an operation on the data.

In some implementations, the memory array further includes second contact structures, and a second contact structure of the second contact structures extends through at least one layer of the n layers of semiconductor structures along the first direction, and is connected to a corresponding second conductive layer of the at least one layer.

In some implementations, the first contact structure is disposed on a side of the first conductive layer or at an end of the first conductive layer, the second contact structure is disposed on a side of the second conductive layer or at an end of the second conductive layer, and the memory device is configured to store weight data and output data obtained after performing an operation on the weight data.

In some implementations, the first conductive layer is a source line layer, and the second conductive layer is a bit line layer, or the first conductive layer is a bit line layer, and the second conductive layer is a source line layer.

In some implementations, the source line layer is located on a side of two rows of the memory structures away from each other, a first portion of the bit line layer is located on a side of the two rows of the memory structures facing each other, and is connected to a second end of the one or more corresponding memory structures, and corresponding memory structures connected to the source line layer are correspondingly connected to two bit line layers, respectively. A second portion of the bit line layer is located on a side of two rows of second contact structures away from each other, and is connected to the two rows of second contact structures, a third portion of the bit line layer connects the first portion and the second portion of the bit line layer, and a gap of the first portion of the bit line layer is smaller than that of the second portion of the bit line layer.

Another aspect of the present disclosure features a memory device including a memory array and a peripheral circuit. The memory array includes n layers of semiconductor structures, memory structures arranged in an array, and first contact structures, where n is an integer greater than 1, and the n layers of semiconductor structures are stacked along a first direction. Each layer of the n layers of semiconductor structures includes a first conductive layer and a second conductive layer that are spaced apart from each other, the first conductive layer being connected to a first end of one or more memory structures of the memory structures, the second conductive layer being connected to a second end of the one or more memory structures of the memory structures, and a first contact structure of the first contact structures extends through at least two layers of the n layers of semiconductor structures along the first direction, and is connected to at least two first conductive layers of the at least two layers.

In some implementations, the memory array further includes second contact structures, and a second contact structure of the second contact structures extends through at least one layer of the n layers of semiconductor structures along the first direction, and is connected to a corresponding second conductive layer of the at least one layer.

In some implementations, the first contact structure is disposed on a side of the first conductive layer or at an end of the first conductive layer, the second contact structure is disposed on a side of the second conductive layer or at an end of the second conductive layer, and the memory device is configured to store weight data and output data obtained after performing an operation on the weight data.

In some implementations, the first conductive layer is a source line layer, and the second conductive layer is a bit line layer, or the first conductive layer is a bit line layer, and the second conductive layer is a source line layer.

In some implementations, the source line layer is located on a side of two rows of the memory structures away from each other, a first portion of the bit line layer is located on a side of the two rows of the memory structures facing each other, and is connected to a second end of the one or more corresponding memory structures, and corresponding memory structures connected to the source line layer are correspondingly connected to two bit line layers, respectively. A second portion of the bit line layer is located on a side of two rows of second contact structures away from each other, and is connected to the two rows of second contact structures, a third portion of the bit line layer connects the first portion and the second portion of the bit line layer, and a gap of the first portion of the bit line layer is smaller than that of the second portion of the bit line layer.

It is to be understood that in examples of the present disclosure, the first conductive layer may be led out by using fewer first contact structures, that is, the number of source/drain lead-out ports is reduced, thereby saving chip area and facilitating improvement of memory density. Meanwhile, the number of the source/drain lead-out ports is reduced so that complexity of circuit connection can be reduced.

### BRIEF DESCRIPTION OF THE DRAWINGS

FIG. 1 is a first schematic structural diagram of a system provided by an example of the present disclosure;

FIG. 2 is a second schematic structural diagram of a system provided by an example of the present disclosure;

FIG. 3 is a first schematic structural diagram of a semiconductor device provided by an example of the present disclosure;

FIG. 4 is a second schematic structural diagram of a semiconductor device provided by an example of the present disclosure;

FIG. 5A is a third schematic structural diagram of a semiconductor device provided by an example of the present disclosure;

FIG. 5B is a fourth schematic structural diagram of a semiconductor device provided by an example of the present disclosure;

FIG. 6 is a fifth schematic structural diagram of a semiconductor device provided by an example of the present disclosure;

FIG. 7 is a sixth schematic structural diagram of a semiconductor device provided by an example of the present disclosure;

FIG. 8 is a first schematic diagram of a circuit structure of a semiconductor device provided by an example of the present disclosure;

FIG. 9 is a second schematic diagram of a circuit structure of a semiconductor device provided by an example of the present disclosure;

FIG. 10 is a first schematic flowchart of a forming method of a semiconductor device provided by an example of the present disclosure;

FIG. 11 is a second schematic flowchart of a forming method of a semiconductor device provided by an example of the present disclosure;

FIG. 12A is a first schematic structural diagram of a forming method of a semiconductor device provided by an example of the present disclosure;

FIG. 12B is a second schematic structural diagram of a forming method of a semiconductor device provided by an example of the present disclosure;

FIG. 12C is a third schematic structural diagram of a forming method of a semiconductor device provided by an example of the present disclosure;

FIG. 12D is a fourth schematic structural diagram of a forming method of a semiconductor device provided by an example of the present disclosure;

FIG. 13A is a fifth schematic structural diagram of a forming method of a semiconductor device provided by an example of the present disclosure;

FIG. 13B is a sixth schematic structural diagram of a forming method of a semiconductor device provided by an example of the present disclosure;

FIG. 13C is a seventh schematic structural diagram of a forming method of a semiconductor device provided by an example of the present disclosure;

FIG. 13D is an eighth schematic structural diagram of a forming method of a semiconductor device provided by an example of the present disclosure;

FIG. 14 is a schematic structural diagram of a memory device provided by an example of the present disclosure;

FIG. 15 is a third schematic structural diagram of a semiconductor structure provided by an example of the present disclosure.

Like reference numbers and designations in the various drawings indicate like elements. It is to be understood that the various exemplary implementations shown in the figures are merely illustrative representations and are not necessarily drawn to scale.

### DETAILED DESCRIPTION

The technical solutions in implementations of the present disclosure will be described below clearly and completely in conjunction with the implementations and the drawings of the present disclosure. Apparently, the implementations described are only part, but not all, of the implementations of the present disclosure. All other implementations obtained by those of ordinary skills in the art based on the implementations in the present disclosure without creative work shall fall within the scope of protection of the present disclosure.

In the following descriptions, a lot of details are given in order to provide the more thorough understanding of the present disclosure. However, it is apparent to those skilled in the art that the present disclosure may be implemented without one or more of these details. In other examples, in order to avoid confusion with the present disclosure, some technical features well-known in the field are not described. That is, not all the features of the actual examples are described here, and well-known functions and structures are not described in detail.

In the drawings, the sizes of a layer, a region, and an element and their relative sizes may be exaggerated for clarity. Like reference numerals denote like elements throughout the specification.

It is to be understood that when an element or a layer is referred to as being “on”, “adjacent to”, “connected to”, or “coupled to” other elements or layers, it may be directly on, adjacent to, connected to, or coupled to the other elements or layers, or intervening elements or layers may be present. In contrast, when an element is referred to as being “directly on”, “immediately adjacent to”, “directly connected to”, or “directly coupled to” other elements or layers, no intervening elements or layers are present. It is to be understood that, although terms first, second, third and the like may be used to describe various elements, components, regions, layers and/or parts, these elements, components, regions, layers and/or parts should not be limited by these terms. These terms are only used to distinguish one element, component, region, layer or part from another element, component, region, layer or part. Thus, a first element, component, region, layer or part discussed below may be represented as a second element, component, region, layer or part, without departing from the teachings of the present disclosure. However, when the second element, component, region, layer or part is discussed, it does not mean that the first element, component, region, layer or part is necessarily present in the present disclosure.

Spatially relative terms, such as “beneath”, “below”, “lower”, “under”, “over”, “upper”, etc., may be used here for ease of description to describe the relationship between one element or feature and other elements or features as illustrated in the figures. It is to be understood that, the spatially relative terms are intended to further encompass different orientations of a device in use or operation in addition to the orientation depicted in the figures. For example, if the device in the drawings is flipped, then the elements or the features described as “below” or “under” or “beneath” other elements may be oriented “on” the other elements or features. Thus, the example terms “below” and “beneath” may comprise both upper and lower orientations. The device may be orientated otherwise (rotated by 90 degrees or other orientations), and the spatially descriptive words used here are interpreted accordingly.

The terms used here are only intended to describe the specific examples, and are not used as limitations to the present disclosure. As used here, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more other features, integers, steps, operations, elements, components, and/or groups. As used here, a term “and/or” comprises any and all combinations of related items listed.

In the present disclosure, the term “substrate” refers to a material onto which subsequent material layers are added. A substrate includes a "top" surface and a "bottom" surface. Unless otherwise specified, the top surface of the substrate is usually the position where semiconductor devices are formed, thus the semiconductor devices are formed on the top side of the substrate. The bottom surface is opposite to the top surface, so the bottom side of the substrate is opposite to the top side of the substrate. A substrate itself can be patterned. Materials added on the top of the substrate can be patterned or can remain non-patterned. Furthermore, the substrate may include a variety of semiconductor materials, such as silicon, germanium, gallium arsenide, indium phosphide and the like. Alternatively, a substrate may be made from a non-conductive material, such as a glass, a plastic, or a sapphire wafer.

In the present disclosure, the term “layer” refers to a material portion comprising a region with a thickness. A layer has a top side and a bottom side, wherein the bottom side of the layer is relatively close to the substrate and the top side is relatively far away from the substrate. A layer may extend over the entire underlying or overlying structure or may have an extent less than the extent of the underlying or overlying structure. Furthermore, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may comprise one or more layers therein, and/or may have one or more layers thereon, thereabove, and/or therebelow. The layer may comprise a plurality of layers. For example, an interconnection layer may comprise one or more conductors and contact layers (in which contacts, interconnection lines, and/or vertical interconnect accesses VIA are formed) and one or more dielectric layers.

In the present disclosure, for ease of description, “tier” is used to refer to elements that have substantially the same height along a vertical direction. For example, a word line and an underlying gate dielectric layer may be referred to as a “tier”, a word line and an underlying insulating layer may be collectively referred to as a “tier”, word lines having substantially the same height may be referred to as a “word line tier” or the like, and so on.

In the present disclosure, the term “horizontal/horizontally/lateral/laterally” means a lateral surface parallel to a substrate, and the term "vertical" or "vertically" means a lateral surface perpendicular to the substrate.

In the present disclosure, the term “3D memory” refers to a three-dimensional (3D) semiconductor device having vertically-oriented strings of memory cell transistors (referred to as “memory strings” in the present disclosure) on a laterally- oriented substrate, such that the memory strings extend in a vertical direction relative to the substrate.

In order to understand the present disclosure thoroughly, detailed operations and detailed structures will be proposed in the following description to set forth the technical solution of the present disclosure. The detailed descriptions of the preferred examples of the present disclosure are as follows. However, the present disclosure may also have other implementations in addition to these detailed descriptions.

In a classical Von Neumann computing architecture, a memory is separate from a processor, and data is transmitted through a data bus between the memory and the processor. When executing a command, the processor first reads the data from the memory, and then writes the updated data back into the memory after processing is completed, the frequent data migration brings huge power consumption and time overheads. In addition, since the memory bandwidth is limited, the processing speed of the processor is limited by the access speed of the memory, which greatly affects the computing performance. With the rise of applications such as big data and artificial intelligence, massive data processing makes the bottleneck of the Von Neumann computing architecture more and more prominent. In order to solve the bottleneck of the classic Von Neumann computing architecture, computing-in-memory chip architecture emerges, and the basic idea is to embed a computing function in the memory and directly use the memory to perform logic computation, thereby reducing data transmission amount and transmission distance between the memory and the processor, reducing power consumption, and improving computing performance, so that a computing system with high computing power, high bandwidth and high energy efficiency is expected to be constructed.

The computing-in-memory chip relies on its own physical characteristics while having both storage and computing abilities. The storage ability refers to the ability of different memories to store values by changing their conductance values thereof according to their physical characteristics, and the computing ability refers to the ability to complete vector matrix multiplication computation within a certain time by constructing an array composed of memory devices according to Ohm’s law and Kirchhoff’s law.

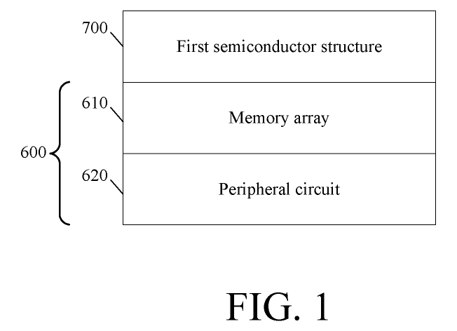

FIG. 1 is an optional schematic structural diagram of a system provided by an example of the present disclosure. The system can be a memory system. Referring to FIG. 1, the system includes a first semiconductor structure 700 and a second semiconductor structure 600. The first semiconductor structure 700 and the second semiconductor structure 600 are connected in a bonding manner. The first semiconductor structure 700 includes an analog-to-digital conversion circuit and a data processing circuit. The second semiconductor structure 600 includes a memory array 610 for performing a first operation and at least a portion of peripheral circuit 620 coupled to the memory array 610. The analog-to-digital conversion circuit is configured to convert analog calculation information obtained by the memory array 610 performing the first operation into digital information. The data processing circuit is configured to perform a second operation on the digital information.

In some examples, the first semiconductor structure 700 and the second semiconductor structure 600 are in different planes and stacked on each other. Moreover, the memory array 610 and the peripheral circuit 620 in the second semiconductor structure 600 may be in different planes and stacked on each other, thereby reducing planar size.

In some examples, the first semiconductor structure 700 and the second semiconductor structure 600 may be formed in parallel on different substrates. For example, the first semiconductor structure 700 is formed on a first substrate, the memory array 610 is formed on a second substrate, and the peripheral circuit 620 is formed on a third substrate. Then, they can be stacked on each other using various bonding techniques such as hybrid bonding, transfer bonding, etc.

In an example of the present disclosure, by vertically integrating the first semiconductor structure 700 and the second semiconductor structure 600, and vertically separating the first semiconductor structure 700, the memory array 610, and the peripheral circuit 620 into different planes, the chip size may be reduced and the memory density can be increased.

In an example of the present disclosure, the second semiconductor structure 600 includes a first sub semiconductor structure formed with the memory array 610 and a second sub semiconductor structure formed with at least a portion of the peripheral circuit 620. In some examples, one portion of the peripheral circuit is formed in the second sub semiconductor structure, and the other portion thereof is formed in the first sub semiconductor structure. In other words, the peripheral circuit of the memory array may be divided into two portions, one portion and the memory array are jointly formed in the first sub semiconductor structure, and the other portion is formed in the second sub semiconductor structure. In other examples, the peripheral circuit may be entirely formed in the second sub semiconductor structure.

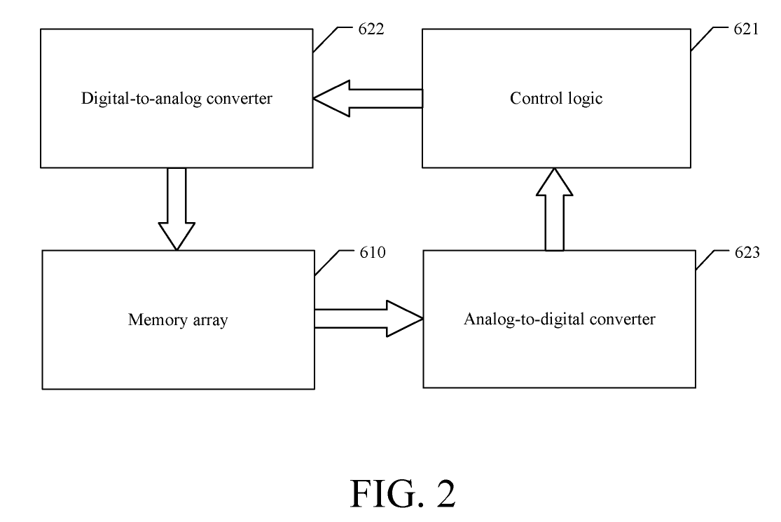

FIG. 2 is a first schematic diagram of a second system including a peripheral circuit and a memory array provided by an example of the present disclosure. Referring to FIG. 2, the peripheral circuit 620 may include a control logic 621, a digital-to-analog converter 622 coupled to the control logic 621 and the memory array 610, and an analog-to-digital converter 623 coupled to the memory array 610 and the control logic 621. When performing a first operation using the second semiconductor structure, the digital-to-analog converter 622 may convert a digital signal into a voltage signal required by the memory array 610 in the second semiconductor structure. The analog-to-digital converter 623 may convert a current signal output by the memory array 610 into a digital signal. The control logic 621 may be coupled to the peripheral circuit and configured to control operations of the peripheral circuit. The control logic 621 may also be configured to receive input data sent by an external device.

In conjunction with FIGS. 1 and 2, when performing the first operation using the second system, the control logic 621 may receive input data sent by an external device (e.g., a host), and the digital-to-analog converter 622 in the peripheral circuit 620 converts the input data into a voltage signal that needs to be applied to a word line or a bit line. The analog calculation information obtained after performing the first operation is transmitted to an analog-to-digital conversion circuit, the analog calculation information is converted into digital information by the analog-to-digital conversion circuit, the final digital information is transmitted to a data processing circuit, and then a second operation is performed on the digital information by the data processing circuit.

In some examples, for a computing-in-memory chip, a first operation between input data and a weight matrix needs to be implemented, the input data may be an input vector or an input matrix composed of a plurality of elements, the weight matrix is composed of a plurality of weights, and a product accumulation operation of each element in the input data and the plurality of weights in the weight matrix needs to be performed to obtain a corresponding element in output data.

To implement the above operation functions, the memory array 610 may be configured to store the weight matrix, and specifically, the weights in the weight matrix may be written into the memory array 610 according to a certain mapping rule, and each memory cell in the memory array 610 may be configured to store one weight. During operation phase, the second semiconductor structure may receive the input data from the external device, the input data may be the input vector or the input matrix composed of the plurality of elements, and each element in the input data may be converted into an input voltage by the digital-to-analog conversion circuit 622, and the input voltage is input into the memory array 610 by the bit line or the word line.

In an example of the present disclosure, the analog calculation information may be output via the bit line or via a source terminal. That is, the bit line in the second semiconductor structure is an analog information output terminal, or the source terminal is an analog information output terminal.

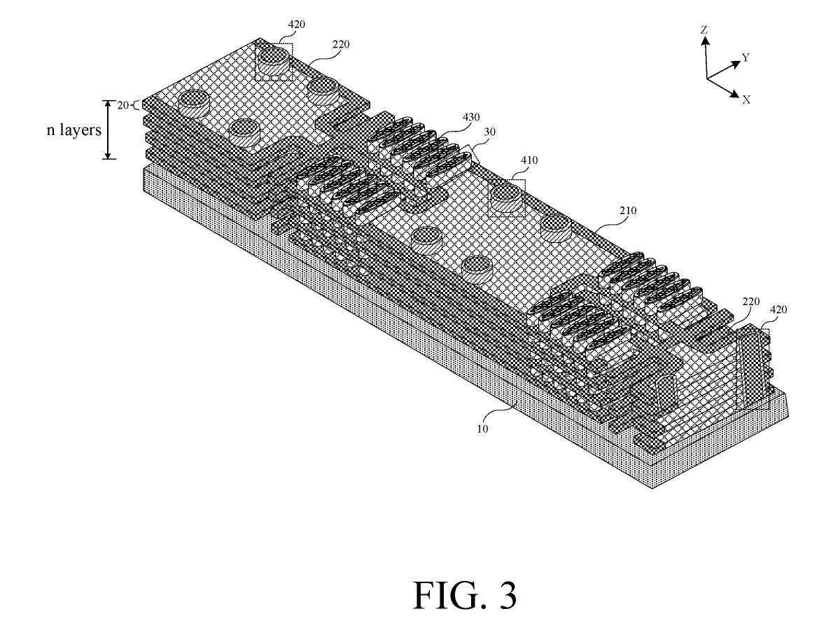

FIG. 3 is an optional schematic structural diagram of a semiconductor device provided by an example of the present disclosure.

As shown in FIG. 3, the semiconductor device includes n layers of semiconductor structures 20, memory structures 30 arranged in an array, and first contact structures 410, where n is greater than 1. The n layers of the semiconductor structures 20 are stacked over a semiconductor layer 10 along a first direction Z, where the first direction Z may be a direction perpendicular to a lateral surface of the semiconductor layer 10.

In an example of the present disclosure, the semiconductor layer 10 may be any suitable semiconductor substrate. In some implementations, the semiconductor layer 10 may be removed in a subsequent process.

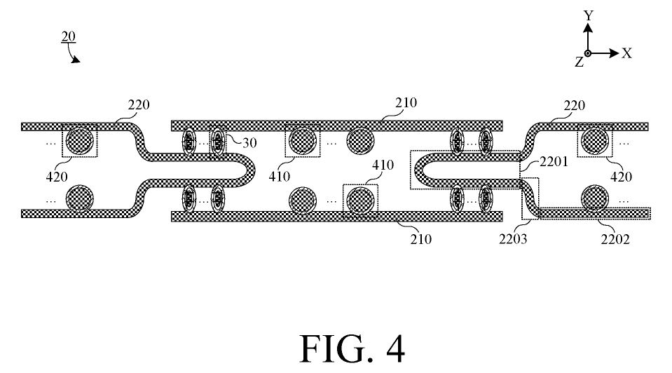

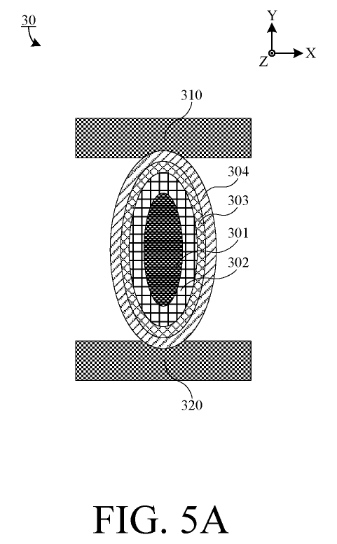

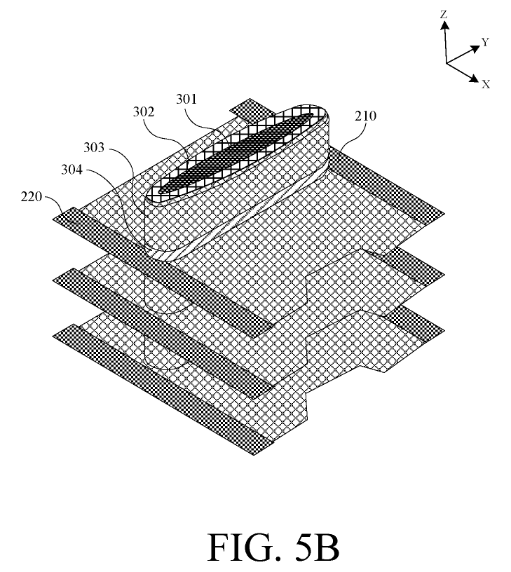

FIGS. 4, 5A, and 5B, show a partial structure in FIG. 3. FIG. 4 is a schematic structural diagram of each layer of the semiconductor structure 20, and FIG. 5A is a schematic structural diagram of the memory structure 30.

In conjunction with FIGS. 3 and 4, each layer of the semiconductor structure 20 includes a first conductive layer 210 and a second conductive layer 220 spaced apart from each other. The first conductive layer 210 is connected to a first end of one or more memory structures 30, and the second conductive layer 220 is connected to a second end of the one or more memory structures 30. The first conductive layer 210 and the second conductive layer 220 may be formed from any suitable conductive material, such as tungsten (W), aluminum (Al), copper (Cu), cobalt (Co), or any combination thereof.

In an example of the present disclosure, referring to FIGS. 5A and 5B, a memory structure 30 includes a control gate 301, a storage layer 302, an isolation layer 303, and a channel layer 304. A voltage applied to the control gate 301 may change a state of the storage layer 302, thereby implementing writing or reading of data.

In some examples of the present disclosure, referring to FIGS. 5A and 5B, the storage layer 302 may be a ferroelectric storage layer, where the ferroelectric storage layer may include a ferroelectric material such as lead zirconate titanate (PZT), strontium bismuth tantalate (SBT), barium titanate (BaTiO₃), and/or lead titanate (PbTiO₃). When a positive electric field is applied to a ferroelectric material, the ferroelectric material is positively polarized. Applying a negative electric field will not depolarize the ferroelectric material until a reverse coercive field is reached, and as the magnitude of the negative electric field increases, the ferroelectric material may be fully polarized in a negative direction. Once again the positive electric field is applied and a coercive field is propagated in a positive direction, the polarization in the ferroelectric material may be again flipped to the positive direction until it is fully polarized to linearly follow the electric field. Ferroelectric polarization is non-volatile because once polarization is generated, the external electric field cannot change the polarization direction until the magnitude of the electric field reaches a threshold. Therefore, the memory structure 30 using the ferroelectric storage layer utilizes polarization reversal or switching effect, and stores data "0" or "1" according to the direction of spontaneous polarization.

In some other examples of the present disclosure, referring to FIGS. 5A and 5B, the storage layer 302 may be a floating gate storage layer, wherein the floating gate storage layer may include a semiconductor material (e.g., polycrystalline silicon). When a higher voltage is applied to the control gate 301, at the same time a source of the memory structure 30 is grounded, and a drain of the memory structure 30 is floating, electrons may reach the floating gate storage layer through tunneling. When the voltage applied on the control gate 301 is removed, electrons will remain in the floating gate storage layer. The charge amount in the floating gate storage layer indicates that the stored data is “0” or “1”.

In an example of the present disclosure, referring to FIGS. 5A and 5B, the isolation layer 303 may be located between the storage layer 302 and the channel layer 304. The isolation layer 303 may be configured to reduce the possibility of material mixing between the storage layer 302 and the channel layer 304. An effective gate dielectric of the memory structure 30 is a combination of the storage layer 302 and the isolation layer 303. A thinner effective gate dielectric may provide better control of the channel layer 304 from the control gate 301.

In some examples of the present disclosure, the isolation layer 303 may include silicon oxide, silicon nitride, silicon oxynitride, high-k dielectric material (e.g., HfO₂, HfAlO, Al₂O₃), and/or any combination thereof. The isolation layer 303 may be disposed by any suitable film deposition technique, such as ALD, CVD, sputtering, evaporation, and/or any combination thereof. The isolation layer 303 may also be formed by oxidation, nitridation, and/or a combination thereof.

In an example of the present disclosure, referring to FIGS. 5A and 5B, the channel layer 304 serves as a channel of the memory structure 30. The channel layer 304 is on the same layer as a first electrode 310/second electrode 320, and the channel layer 304 does not extend through the stacked layers. In some examples of the present disclosure, the channel layer 304 may include amorphous silicon, polycrystalline silicon, monocrystalline silicon, and/or any combination thereof. The channel layer 304 may be disposed by any suitable thin film deposition technique, such as ALD, CVD, sputtering, etc.

In an example of the present disclosure, referring to FIGS. 5A and 5B, the first end of the memory structure 30 is connected to the first electrode 310. The first electrode 310 in FIG. 5A may be formed by the first conductive layer 210 in FIG. 5B. Correspondingly, the second end of the memory structure 30 is connected to the second electrode 320. The second electrode 320 in FIG. 5A may be formed by the second conductive layer 220 in FIG. 5B. The first end of the memory structure 30 may serve as one of the source and the drain of the memory structure 30, and the second end of the memory structure 30 may serve as the other of the source and the drain of the memory structure 30.

In an example of the present disclosure, referring to FIGS. 5A and 5B, 304 is on the same layer as 310/320, and does not extend through the stacked layers like 301/302/303.

In an example of the present disclosure, in conjunction with FIGS. 3 and 5A, the control gate 301 in FIG. 5A may be formed by a third contact structure 230 in FIG. 3. The third contact structure 230 and the storage layer 302 of the memory structure 30 extend through the n layers of the semiconductor structures 20 along the first direction Z. The storage layer 302 surrounds a sidewall of the third contact structure 230. The third contact structure 230 is connected to a word line layer (not shown in the figures). That is, the control gate 301 of the memory structure 30 is led out from the third contact structure 230 and connected to the word line layer. An outer sidewall of the storage layer 302 is covered with the isolation layer 303. The channel layer 304 is located at an intersection of the isolation layer 303 and respective one of the n layers of the semiconductor structures 20.

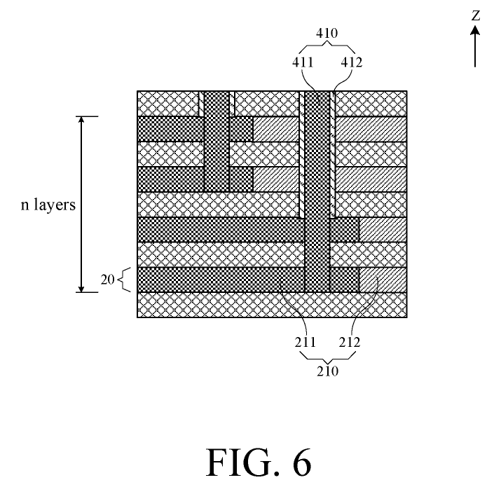

FIG. 6 is a schematic structural diagram of the first contact structure 410 taken along the first direction Z. In conjunction with FIGS. 3 and 6, the first contact structure 410 extends through at least two layers of the semiconductor structures 20 along the first direction Z and is connected to at least two layers of the first conductive layers 210. That is, the first conductive layers 210 in the at least two layers of the semiconductor structures 20 may be connected to a conductive structure in the same first contact structure 410 and led out from that first contact structure 410.

It may be understood that the first conductive layers 210 can be led out by using fewer first contact structures 410, that is, the number of source/drain led-out ports is reduced, thereby saving chip area and facilitating improvement of memory density. Meanwhile, the number of source/drain led-out ports is reduced so that complexity of circuit connection can be reduced.

In an example of the present disclosure, referring to FIG. 6, the first conductive layer 210 and the first contact structure 410 may adopt a self-align contact (SCT) process, wherein the SCT process precisely stops a contact hole on each conductive layer by using a stair step (SS) cutting process.

It may be understood that since there are fewer first contact structures 410 in the example of the present disclosure, there are fewer contact holes required to be formed in the SCT process, thereby reducing the process difficulty.

In an example of the present disclosure, referring to FIG. 3, the semiconductor device further comprises a second contact structure 420.

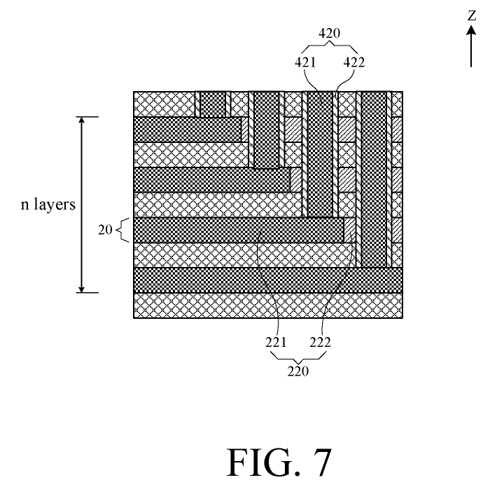

FIG. 7 is a schematic structural diagram of the second contact structure 420 taken along the first direction Z. In conjunction with FIGS. 3 and 7, the second contact structure 420 extends through at least one layer of the semiconductor structures 20 along the first direction Z and is connected to one second conductive layer 220. That is, the second conductive layer 220 in one layer of the semiconductor structures 20 may be connected to one second contact structure 420 and led out from the second contact structure 420.

In an example of the present disclosure, referring to FIG. 6, the first contact structure 410 may be disposed on a side of the first conductive layer 210 or at an end of the first conductive layer 210. That is, the first contact structure 410 may be in contact with a side of the first conductive layer 210, or the first contact structure 410 may be in contact with an end of the first conductive layer 210.

Correspondingly, referring to FIG. 7, the second contact structure 420 may be disposed on a side of the second conductive layer 220 or at an end of the second conductive layer 220. That is, the second contact structure 420 may be in contact with a side of the second conductive layer 220, or the second contact structure 420 may be in contact with an end of the second conductive layer 220.

In an example of the present disclosure, referring to FIGS. 3 or 4, the first contact structure 410 may be disposed between the memory structures 30, and the second contact structure 420 may be disposed at periphery of the memory structures 30.

In an example of the present disclosure, the first conductive layer 210 is a source line layer, and the second conductive layer 220 is a bit line layer. Alternatively, the first conductive layer 210 is a bit line layer, and the second conductive layer 220 is a source line layer. The source line layer and the bit line layer are connected to two ends of the memory structure 30, respectively, wherein the source line layer is configured to provide carriers (i.e., current) for the memory structure 30, and the bit line layer is configured to transmit data during read and write procedures.

In some examples of the present disclosure, referring to FIG. 4, the first conductive layer 210 is a source line layer, and the second conductive layer 220 is a bit line layer. The source line layer 210 is located on a side of two rows of memory structures 30 away from each other. A first portion 2201 of the bit line layer 220 is located on a side of two rows of memory structures 30 facing each other, and is connected to the second end of the memory structure. The memory structures 30 connected to the same source line layer 210 are correspondingly connected to two bit line layers 220, respectively.

Still referring to FIG. 4, a second portion 2202 of the bit line layer 220 is located on a side of two rows of second contact structures 420 away from each other, and is connected to the second contact structure 420. A third portion 2203 of the bit line layer 220 connects the first portion 2201 and the second portion 2202 of the bit line layer 220. A first gap of the first portion 2201 of the bit line layer 220 is smaller than a second gap of the second portion 2202 of the bit line layer 220. For example, as illustrated in FIG. 4, the first portion 2201 can include two opposite segments that are spaced from each other with the first gap along the Y direction, and the second portion 2202 can include two opposite segments that are spaced from each other with the second gap along the Y direction. The first gap is smaller than the second gap along the Y direction.

In some other examples of the present disclosure, referring to FIG. 4, the first conductive layer 210 is a bit line layer, and the second conductive layer 220 is a source line layer. That is, the purposes of the first conductive layer 210 and the second conductive layer 220 may be exchanged.

It should be noted that when the purposes of the first conductive layer 210 and the second conductive layer 220 are exchanged, it is also necessary to ensure that the output terminals are not connected in parallel. If the output terminals are connected in parallel, the parallelism will be reduced. Therefore, if the output terminals are bit line layers, the source line layers are connected in parallel, and the first contact structures 410 are connected to the source line layers. Otherwise, if the output terminals are source line layers, the bit line layers are connected in parallel.

In some examples of the present disclosure, referring to FIG. 6, the first contact structure 410 may include a conductive structure 411 and an insulating layer 412. The insulating layer 412 surrounds a sidewall of the conductive structure 411, and the insulating layer 412 is configured to insulate the conductive structure 411 from other semiconductor structures. The conductive structure 411 may be formed from any suitable conductive material, such as tungsten (W), aluminum (Al), copper (Cu), cobalt (Co), or any combination thereof. The insulating layer 412 may be formed from any suitable insulating material, such as silicon oxide, silicon nitride, silicon oxynitride, high-k dielectric material (e.g., HfO₂, HfAlO, Al₂O₃), and/or any combination thereof.

In some examples of the present disclosure, referring to FIG. 6, each source line layer 210 includes a conductive portion 211 and an insulating portion 212. The conductive portion 211 and the insulating portion 212 are located on two sides of the first contact structure 410, respectively. The conductive portion 211 may be formed from any suitable conductive material, such as tungsten (W), aluminum (Al), copper (Cu), cobalt (Co), or any combination thereof. The insulating portion 212 may be formed from any suitable insulating material, such as silicon oxide, silicon nitride, silicon oxynitride, and/or any combination thereof.

In some examples of the present disclosure, referring to FIG. 7, the second contact structure 420 may include a conductive structure 421 and an insulating layer 422. The insulating layer 422 surrounds a sidewall of the conductive structure 421, and the insulating layer 422 is configured to insulate the conductive structure 421 from other semiconductor structures. The conductive structure 421 may be formed from any suitable conductive material, such as tungsten (W), aluminum (Al), copper (Cu), cobalt (Co), or any combination thereof. The insulating layer 422 may include silicon oxide, silicon nitride, silicon oxynitride, high-k dielectric material (e.g., HfO₂, HfAlO, Al₂O₃), and/or any combination thereof.

In some examples of the present disclosure, referring to FIG. 7, each bit line layer 220 includes a conductive portion 221 and an insulating portion 222. The conductive portion 221 may be formed from any suitable conductive material, such as tungsten (W), aluminum (Al), copper (Cu), cobalt (Co), or any combination thereof. The insulating portion 222 may be formed from any suitable insulating material, such as silicon oxide, silicon nitride, silicon oxynitride, and/or any combination thereof.

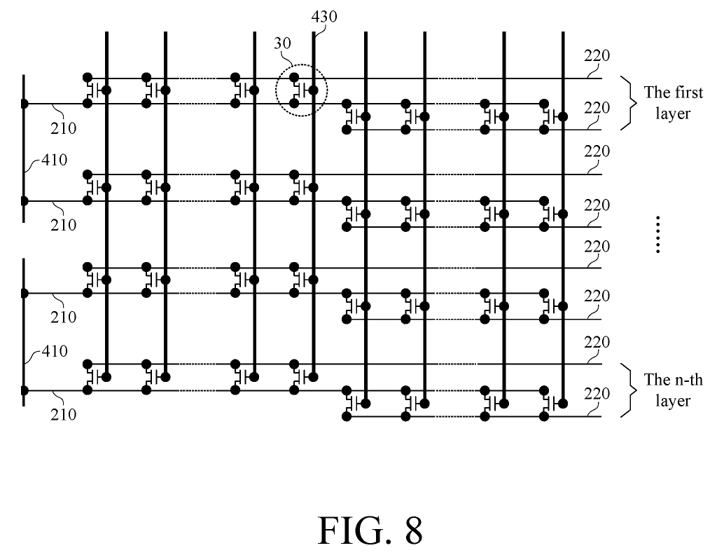

FIG. 8 is a schematic diagram of an optional circuit structure of a semiconductor device provided by an example of the present disclosure.

Referring to FIG. 8, the first end of the memory structure 30 is connected to the first conductive layer 210, the second end of the memory structure 30 is connected to the second conductive layer 220, and the control gate of storage structure 30 is connected to a third contact structure 430.

Still referring to FIG. 8, the first conductive layers 210 in at least two layers of the semiconductor structures may be connected to the same first contact structure 410. That is, the first contact structure 410 may connect the first conductive layers 210 in the at least two layers of the semiconductor structures in parallel. Since the control gates of the memory structures 30 in the n layers of the semiconductor structures are connected to the same third contact structure 430, the memory structures 30 in the n layers of the semiconductor structures may be turned on under the control of one word line signal. Further, the signals on the first conductive layers 210 connected in parallel in the at least two layers of the semiconductor structures may simultaneously act on the memory structures 30 in the at least two layers of the semiconductor structures. In this way, the memory structures 30 in the at least two layers of the semiconductor structures may perform more than two logical operations (e.g., multiplication and addition operations), thereby improving the operation efficiency.

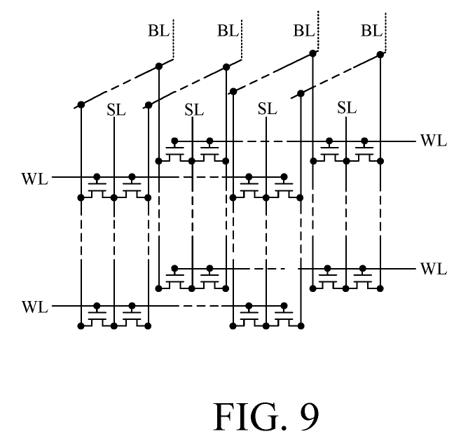

FIG. 9 is a schematic diagram of an optional circuit structure of a semiconductor device provided by an example of the present disclosure.

In FIG. 9, two adjacent bit line layers BL are connected in parallel, while the source line layers SL are not connected in parallel. That is, the first conductive layers 210 connected in parallel shown in FIG. 8 may serve as the bit line layers BL shown in FIG. 9, and the second conductive layers 220 that are not connected in parallel shown in FIG. 8 may serve as the source line layers SL shown in FIG. 9.

In an example of the present disclosure, in order to ensure parallelism, it is necessary to ensure that the output terminals are not connected in parallel. Therefore, if the output terminals are bit line layers, the source line layers are connected in parallel. Otherwise, if the output terminals are source line layers, the bit line layers are connected in parallel. That is, in the example shown in FIG. 9, the bit line layers BL connected in parallel do not serve as the output terminals, but the source line layers SL serve as the output terminals.

It may be understood that the semiconductor device provided by the examples of the present disclosure can realize operations with higher parallelism. Meanwhile, the number of the first conductive layers 210 connected in parallel may be customized according to demand, that is, the parallelism of operations may be adjusted according to demand, thereby improving flexibility.

Based on a concept similar to the above semiconductor device, an example of the present disclosure further provides a forming method of a semiconductor device.

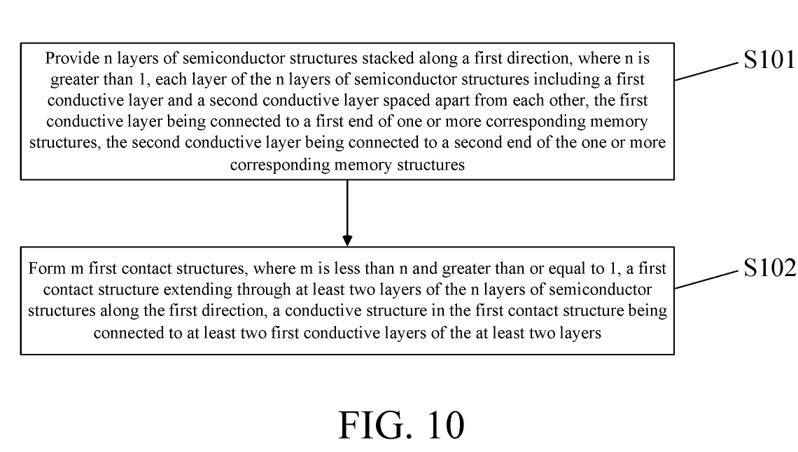

FIG. 10 is an optional schematic flowchart of a forming method of forming a semiconductor device provided by an example of the present disclosure. As shown in FIG. 10, the forming method of the semiconductor device includes operations S101-102, which will be described in conjunction with each operation.

S101: providing n layers of semiconductor structures stacked along a first direction, where n is greater than 1, and each layer of the semiconductor structure includes a first conductive layer and a second conductive layer spaced apart from each other, the first conductive layer is connected to a first end of one or more corresponding memory structures, and the second conductive layer is connected to a second end of the one or more corresponding memory structures.

In an example of the present disclosure, referring to FIG. 3, the n layers of the semiconductor structures 20 are stacked over the semiconductor layer 10 along the first direction Z, where the first direction Z may be a direction perpendicular to a lateral surface of the semiconductor layer 10. The semiconductor layer 10 may be any suitable semiconductor substrate. In some implementations, the semiconductor layer 10 may be removed in a subsequent process.

In an example of the present disclosure, referring to FIGS. 3 or 4, each layer of the semiconductor structure 20 includes the first conductive layer 210 and the second conductive layer 220 spaced apart from each other. The first conductive layer 210 and the second conductive layer 220 may be formed from any suitable conductive material, such as tungsten (W), aluminum (Al), copper (Cu), cobalt (Co), or any combination thereof.

In an example of the present disclosure, forming the first conductive layer 210 and the second conductive layer 220 may include: etching on each layer of the semiconductor structure 20 to form a horizontal trench; and then depositing a conductive material in the horizontal trench to form the first conductive layer 210 and the second conductive layer 220. The conductive material may be deposited into the horizontal trench by using a suitable deposition method, such as CVD, PVD, plasma enhanced chemical vapor deposition (PECVD), sputtering, metal organic chemical vapor deposition (MOCVD), and/or atomic layer deposition (ALD).

In an example of the present disclosure, referring to FIG. 5A, the memory structure 30 includes a control gate 301, a storage layer 302, an isolation layer 303, and a channel layer 304. A voltage applied to the control gate 301 may change a state of the storage layer 302, thereby implementing writing or reading of data. The storage layer 302 may be a ferroelectric storage layer or a floating gate storage layer.

In an example of the present disclosure, in conjunction with FIGS. 3 and 5A, the third contact structure 230 and the storage layer 302 of the memory structure 30 extend through the n layers of the semiconductor structures 20 along the first direction Z. The third contact structure 230 in FIG. 3 may form the control gate 301 in FIG. 5A. The storage layer 302 surrounds a sidewall of the third contact structure 230. The third contact structure 230 is connected to a word line layer (not shown in the figures). That is, the control gate 301 of the memory structure 30 is led out from the third contact structure 230 and connected to the word line layer. An outer sidewall of the storage layer 302 is covered with the isolation layer 303. The channel layer 304 is located at an intersection of the isolation layer 303 and respective one of the n layers of the semiconductor structures 20.

In an example of the present disclosure, referring to FIGS. 3 or 4, the first conductive layer 210 is connected to the first end of the memory structure 30, and the second conductive layer 220 is connected to the second end of the memory structure 30. The first end of the memory structure 30 may serve as one of a source and a drain of the memory structure 30, and the second end of the memory structure 30 may serve as the other of the source and the drain of the memory structure 30.

In an example of the present disclosure, referring to FIGS. 3 or 4, the first conductive layer 210 is a source line layer, and the second conductive layer 220 is a bit line layer. Alternatively, the first conductive layer 210 is a bit line layer, and the second conductive layer 220 is a source line layer. The source line layer and the bit line layer are connected to two ends of the memory structure 30, respectively, where the source line layer is configured to provide carriers (i.e., current) for the memory structure 30, and the bit line layer is configured to transmit data during read and write procedures.

S102: forming m first contact structures, where m is less than n and greater than or equal to 1, a first contact structure extends through at least two layers of the semiconductor structures along the first direction, and a conductive structure in the first contact structure is connected to at least two of the first conductive layers.

In an example of the present disclosure, in conjunction with FIGS. 3 and 6, the first contact structure 410 extends through at least two layers of the semiconductor structures 20 along the first direction Z and is connected to at least two of the first conductive layers 210. That is, the first conductive layers 210 in the at least two layers of the semiconductor structures 20 may be connected to the same first contact structure 410 and led out from that first contact structure 410.

It may be understood that the first conductive layer 210 can be led out by using fewer first contact structures 410, that is, the number m of first contact structures 410 is less than the number n of layers of semiconductor structures 20. In this way, the number of source/drain led-out ports is reduced, thereby saving chip area and facilitating improvement of memory density. Meanwhile, the number of source/drain led-out ports is reduced so that complexity of circuit connection can be reduced.

In an example of the present disclosure, referring to FIG. 6, the first conductive layer 210 and the first contact structure 410 may adopt a self-align contact (SCT) process, wherein the SCT process precisely stops a contact hole on each conductive layer by using a stair step (SS) cutting process.

It may be understood that since there are fewer first contact structures 410 in the example of the present disclosure, there are fewer contact holes required to be formed in the SCT process, thereby reducing the process difficulty.

In an example of the present disclosure, referring to FIGS. 3 or 4, the first contact structure 410 may be disposed between the memory structures 30, and the second contact structure 420 may be disposed at periphery of the memory structures 30.

In some examples of the present disclosure, referring to FIG. 4, the first conductive layer 210 is a source line layer, and the second conductive layer 220 is a bit line layer. The source line layer 210 is located on a side of two rows of memory structures 30 away from each other. The first portion 2201 of the bit line layer 220 is on a side of two rows of memory structures 30 facing each other, and is connected to the second end of the memory structure. The memory structures 30 connected to the same source line layer 210 are correspondingly connected to two bit line layers 220, respectively.

Still referring to FIG. 4, the second portion 2202 of the bit line layer 220 is located on a side of two rows of second contact structures 420 away from each other, and is connected to the second contact structure 420. The third portion 2203 of the bit line layer 220 connects the first portion 2201 and the second portion 2202 of the bit line layer 220. A gap of the first portion 2201 of the bit line layer 220 is smaller than that of the second portion 2202 of the bit line layer 220.

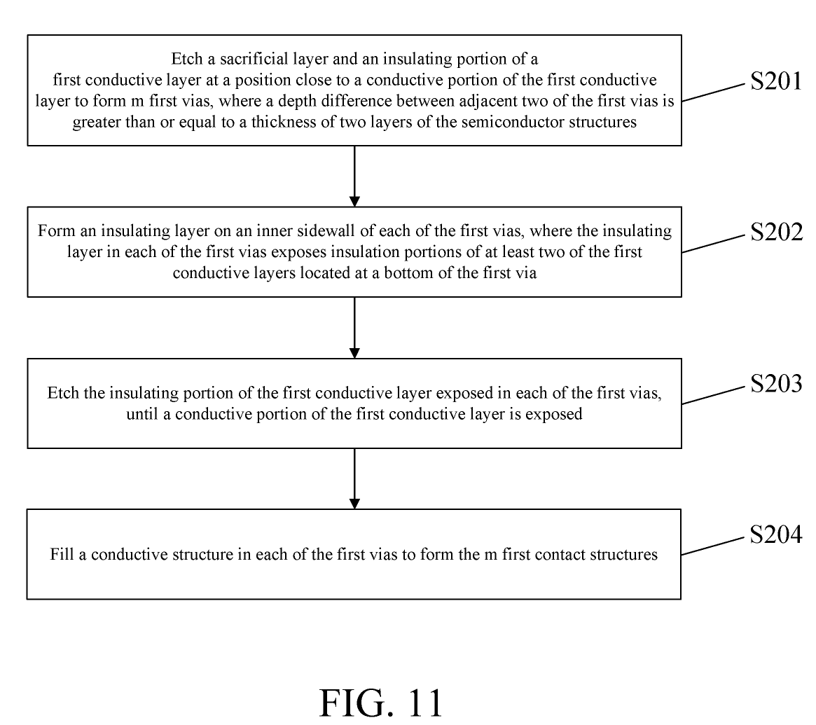

In some examples of the present disclosure, a method for forming m first contact structures includes operations S201-S204 shown in FIG. 11. That is, operation 102 shown in FIG. 10 may be implemented through operations S201-S204 shown in FIG. 11, which will be described in conjunction with each operation.

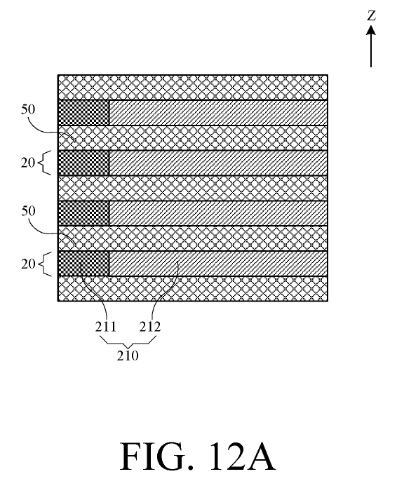

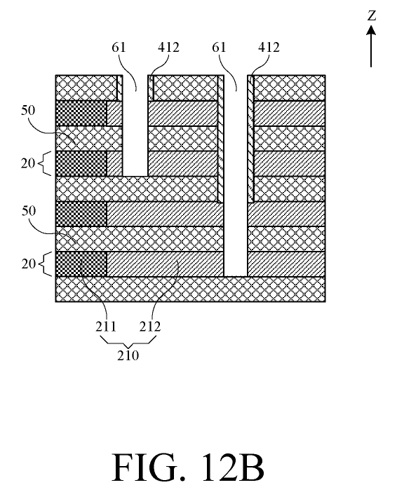

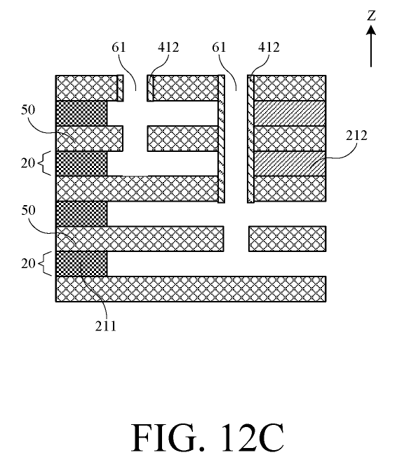

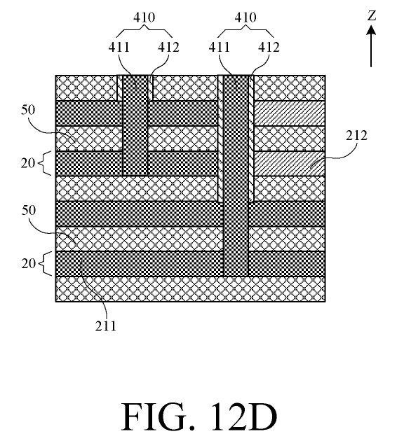

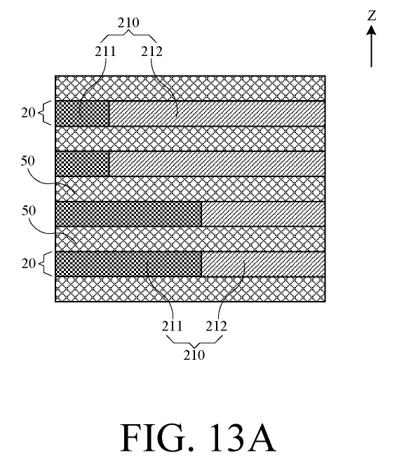

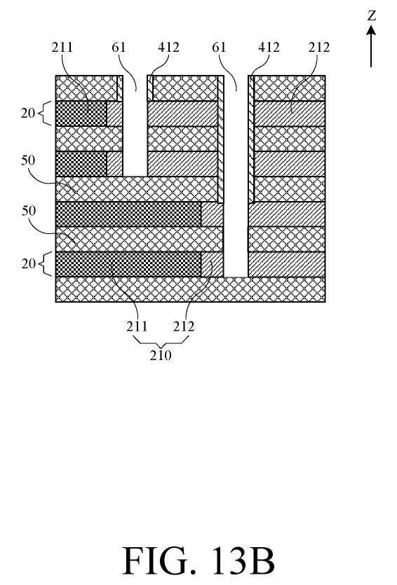

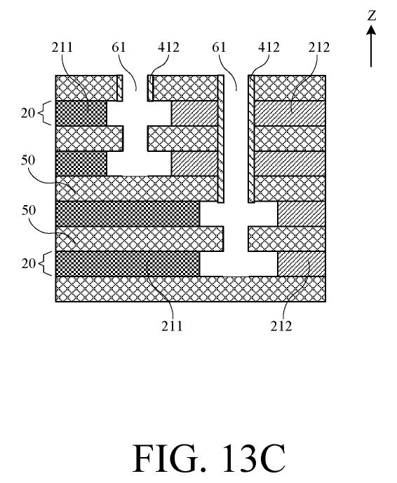

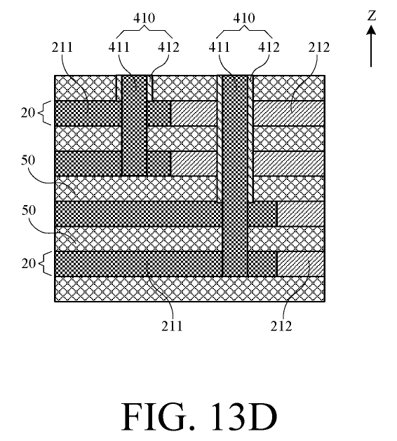

It should be noted that FIGS. 12A to 12D and FIGS. 13A to 13D are schematic structural diagrams of each operation in a forming method of a semiconductor device, for illustrating each operation.

The present disclosure provides two implementations to form the first contact structure 410. These two implementations are shown in FIGS. 12A to 12D, and FIGS. 13A to 13D, respectively. In FIGS. 12A to 12D, the conductive portion 211 of the first conductive layer 210 does not form a stepped structure, and a first contact structure 410 is formed based on this. In FIGS. 13A-13D, the conductive portion 211 of the first conductive layer 210 is a stepped structure, and the first contact structure 410 is formed based on this.

S201: etching a sacrificial layer and an insulating portion of the first conductive layer at a position close to a conductive portion of the first conductive layer to form m first vias, where a depth difference between two adjacent first vias is greater than or equal to a thickness of two layers of the semiconductor structures.

In an example of the present disclosure, referring to FIGS. 12A or 13A, the first conductive layer 210 includes a conductive portion 211 and an insulating portion 212. The conductive portion 211 may be formed from any suitable conductive material, such as tungsten (W), aluminum (Al), copper (Cu), cobalt (Co), or any combination thereof. The insulating portion 212 may be formed from any suitable insulating material, such as silicon oxide, silicon nitride, silicon oxynitride, and/or any combination thereof.

In an example of the present disclosure, referring to FIGS. 12B or 13B, a first via 61 may be formed by etching (e.g., dry etching) a sacrificial layer 50 and the insulating portion 212 of the first conductive layer 210. Each first via 61 is configured to lead out the first conductive layers 210 in at least two layers of the n layers of semiconductor structures 20, so that each first via 61 is etched to at least two layers of the n layers of semiconductor structures 20 to which it correspond. Therefore, a depth difference between two adjacent first vias 61 is greater than or equal to a thickness of two layers of the semiconductor structures 20.

In some examples of the present disclosure, referring to FIG. 12A, the conductive portion 211 of the first conductive layer 210 does not form a stepped structure. That is, in each layer of the semiconductor structure 20, the boundaries of the conductive portions 211 of the first conductive layers 210 are substantially aligned. In conjunction with FIG. 12B, for the first conductive layers 210 in the upper two layers of semiconductor structures 20, the first via 61 is formed at a position closer to the conductive portion 211. For the first conductive layers 210 in the lower two layers of semiconductor structures 20, the first via 61 is formed at a position farther away from the conductive portion 211, so that each first via 61 may be staggered.

In some other examples of the present disclosure, referring to FIG. 13A, the conductive portion 211 of the first conductive layer 210 is a stepped structure. That is, the boundaries of the conductive portions 211 in the lower two layers of semiconductor structures 20 protrude further outward, compared to the conductive portions 211 in the upper two layers of semiconductor structures 20. In conjunction with FIG. 13B, the first via 61 may be formed at a position close to the conductive portion 211 in the corresponding two layers of semiconductor structures 20, so that each first via 61 may be staggered.

S202: forming an insulating layer on an inner sidewall of each first via, wherein the insulating layer in each first via exposes insulation portions of at least two of the first conductive layers located at a bottom of the first via.

In an example of the present disclosure, referring to FIGS. 12B or 13B, an insulating layer 412 may be formed on an inner sidewall of each first via 61. The insulating layer 412 may be formed using any suitable deposition method, such as CVD, PVD, and/or atomic layer deposition (ALD). The insulating layer 412 may be formed from any suitable insulating material, such as silicon oxide, silicon nitride, silicon oxynitride, high-k dielectric material (e.g., HfO₂, HfAlO, Al₂O₃), and/or any combination thereof.

In an example of the present disclosure, still referring to FIGS. 12B or 13B, the insulating layer 412 in each first via 61 does not cover the bottom of the first via 61, so that insulation portions 212 of at least two of the first conductive layers 210 located at the bottom of the first via 61 may be exposed.

S203: etching the insulating portion of the first conductive layer exposed in each first via, until the conductive portion of the first conductive layer is exposed.

In an example of the present disclosure, in conjunction with FIGS. 12B and 12C, or in conjunction with FIGS. 13B and 13C, the insulating portion 212 of the first conductive layer 210 exposed in each first via 61 may be etched (e.g., wet etched) until the conductive portion 211 of the first conductive layer 210 is exposed. In the process of etching the exposed insulation portion 212 of the first conductive layer 210, other portions of the first via 61 are protected by the insulating layer 412 and thus are not etched.

S204: filling a conductive structure in each first via to form m first contact structures.

In an example of the present disclosure, in conjunction with FIGS. 12C and 12D, or in conjunction with FIGS. 13C and 13D, after exposing the conductive portion 211 of the first conductive layer 210 in each first via 61, a conductive structure 411 may be filled in each first via 61, so that the first contact structure 410 is formed. The conductive structure 411 may be formed from any suitable conductive material, such as tungsten (W), aluminum (Al), copper (Cu), cobalt (Co), or any combination thereof. The conductive structure 411 may be formed in the first via 61 by using a suitable deposition method, such as CVD, PVD, plasma enhanced chemical vapor deposition (PECVD), sputtering, metal organic chemical vapor deposition (MOCVD), and/or atomic layer deposition (ALD).

In an example of the present disclosure, referring to FIGS. 12D or 13D, the conductive structure 411 of the first contact structure 410 and the conductive portion 211 of the first conductive layer 210 form electrical contact, so that the first contact structure 410 may lead out the first conductive layer 210.

In an example of the present disclosure, the first contact structure 410 may be disposed on a side of the first conductive layer 210 or at an end of the first conductive layer 210.

In an example of the present disclosure, the forming method of the semiconductor device further includes operation 103, which will be described in conjunction with each operation.

S103: forming n second contact structures at a position close to a conductive portion of the second conductive layer, wherein the second contact structure extends through at least one layer of the semiconductor structures along the first direction, and is connected to one second conductive layer.

In an example of the present disclosure, referring to FIG. 7, the second contact structure 420 is formed at a position close to the conductive portion 221 of the second conductive layer 220. The second contact structure 420 extends through at least one layer of the semiconductor structures 20 along the first direction Z, and is connected to one second conductive layer 220. Therefore, the number of second contact structures 420 is n, corresponding to the number of layers of semiconductor structures 20.

In an example of the present disclosure, the second contact structure 420 may be disposed on a side of the second conductive layer 220 or at an end of the second conductive layer 220.

Based on a concept similar to the above semiconductor device, an example of the present disclosure further provides a memory device.

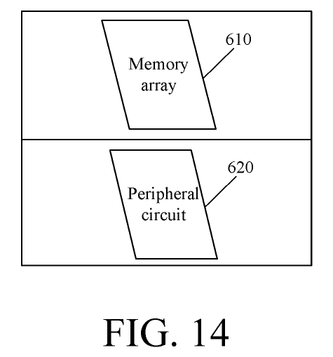

FIG. 14 is an optional schematic structural diagram of a memory device provided by an example of the present disclosure. As shown in FIG. 14, the memory device includes a memory array 610 and a peripheral circuit 620.

Referring to FIG. 14, components of the memory device (the memory array 610 and the peripheral circuit 620) may be separately formed on different substrates and bonded to each other to form a bonded chip. A first semiconductor structure 600 includes the memory array 610, and a second semiconductor structure 700 includes the peripheral circuit 620.

In an example of the present disclosure, the peripheral circuit 620 (also referred as control and sensing circuit) may include any suitable digital, analog, and/or mixed signal circuit for facilitating operations of the memory array. For example, the peripheral circuit 620 may include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any part of a functional circuit mentioned above (e.g., sub circuit), or any active or passive component of a circuit (e.g., transistor, diode, resistor or capacitor). According to some implements, the peripheral circuit 620 in the second semiconductor structure 700 uses complementary metal oxide semiconductor (CMOS) technology, which may be implemented using logic processes (e.g., technology nodes of 90nm, 65nm, 60nm, 45nm, 32nm, 28nm, 22nm, 20nm, 16nm, 14nm, 10nm, 7nm, 5nm, 3nm, 2nm, etc.).

In an example of the present disclosure, the memory array 610 includes any other suitable type of memory array that may include a transistor used as a switch and a selection device, such as PCM cell array, static random access memory (SRAM) cell array, FRAM cell array, resistive memory array, magnetic memory array, spin transfer torque (STT) memory array, or any combination thereof.

In an example of the present disclosure, the memory device shown in FIG. 14 may adopt a computing-in-memory architecture. The computing-in-memory architecture, also referred as computation-in-memory or computing-in-memory, is an architecture that integrates storage and computing functions on the same chip. The computing-in-memory architecture may perform calculation on data by using a memory, thereby avoiding the “memory wall” and “power consumption wall” caused by data transfer, greatly improving the parallelism of data and energy efficiency.

The memory structure in the memory array 610 may be configured to store weight data and output data obtained after performing an operation on the weight data. That is, when an operation (i.e. a first operation) needs to performed on the weight data, the operation procedure does not need to transfer the data from the memory to a separate processor for execution, but is directly completed inside the memory, which greatly reduces delay and power consumption of data transmission and improves operation efficiency. Meanwhile, outputting the data obtained after performing an operation on the weight data is also directly completed in the memory, so that the operation result can be immediately used in subsequent operations or decision processes without additional data transfer operations.

As shown in FIG. 8, during a phase of performing the first operation using the memory array, the peripheral circuit is configured to apply a read voltage Vrd to a target word line coupled to the target memory cell 30, apply a corresponding input voltage Vin to the first conductive layer 210 coupled to the target memory cell, and then obtain analog calculation information by sensing a current on the second conductive layer 220 coupled to the target memory cell. For example, by sensing current Io1 on the first conductive layer 220 and converting the current Io1, a product between an element corresponding to the input voltage Vin and a weight corresponding to the read voltage Vrd may be obtained.

In some examples, the peripheral circuit is configured to apply a corresponding programming voltage to the target word line coupled to the target memory block to program the memory cell coupled to the target word line before performing the first operation using the memory array.

In an example of the present disclosure, in conjunction with FIGS. 3 and 14, the memory array 610 includes the n layers of semiconductor structures 20, the memory structures 30 arranged in an array, and the first contact structures 410, wherein n is greater than 1. The n layers of the semiconductor structures 20 are stacked over the semiconductor layer 10 along the first direction Z, wherein the first direction Z may be a direction perpendicular to a lateral surface of the semiconductor layer 10.

With continued conjunction with FIGS. 3 and 14, each layer of the semiconductor structure 20 includes the first conductive layer 210 and the second conductive layer 220 spaced apart from each other. The first conductive layer 210 is connected to the first end of the memory structure 30, and the second conductive layer 220 is connected to the second end of the memory structure 30.

In an example of the present disclosure, in conjunction with FIGS. 3 and 6, the first contact structure 410 extends through at least two layers of the semiconductor structures 20 along the first direction Z and is connected to at least two of the first conductive layer 210.

It may be understood that the first conductive layer 210 can be led out by using fewer first contact structures 410, that is, the number of source/drain led-out ports is reduced, thereby saving chip area and facilitating improvement of memory density. Meanwhile, the number of source/drain led-out ports is reduced so that complexity of circuit connection can be reduced.

In an example of the present disclosure, in conjunction with FIGS. 3 and 7, the memory array further includes the second contact structure 420. The second contact structure 420 extends through at least one layer of the semiconductor structures 20 along the first direction Z and is connected to one second conductive layer 220.

In an example of the present disclosure, referring to FIG. 6, the first contact structure 410 may be disposed on a side of the first conductive layer 210 or at an end of the first conductive layer 210. Correspondingly, referring to FIG. 7, the second contact structure 420 may be disposed on a side of the second conductive layer 220 or at an end of the second conductive layer 220.

In an example of the present disclosure, referring to FIGS. 3 or 4, the first contact structure 410 may be disposed between the memory structures 30, and the second contact structure 420 may be disposed at periphery of the memory structures 30.

In an example of the present disclosure, the first conductive layer 210 is a source line layer, and the second conductive layer 220 is a bit line layer. Alternatively, the first conductive layer 210 is a bit line layer, and the second conductive layer 220 is a source line layer. The source line layer and the bit line layer are connected to two ends of the memory structure 30, respectively, wherein the source line layer is configured to provide carriers (i.e., current) for the memory structure 30, and the bit line layer is configured to transmit data during read and write procedures.

In some examples of the present disclosure, referring to FIG. 4, the first conductive layer 210 is a source line layer, and the second conductive layer 220 is a bit line layer. The source line layer 210 is located on a side of two rows of memory structures 30 away from each other. The first portion 2201 of the bit line layer 220 is located on a side of the two rows of memory structures 30 facing each other, and is connected to the second end of the memory structure. The memory structures 30 connected to the same source line layer 210 are correspondingly connected to two bit line layers 220, respectively.

Still referring to FIG. 4, the second portion 2202 of the bit line layer 220 is located on a side of two rows of second contact structures 420 away from each other, and is connected to the second contact structure 420. The third portion 2203 of the bit line layer 220 connects the first portion 2201 and the second portion 2202 of the bit line layer 220. A gap of the first portion 2201 of the bit line layer 220 is smaller than that of the second portion 2202 of the bit line layer 220.

In some examples of the present disclosure, referring to FIG. 6, the first contact structure 410 may include the conductive structure 411 and the insulating layer 412. The insulating layer 412 surrounds a sidewall of the conductive structure 411, and the insulating layer 412 is configured to insulate the conductive structure 411 from other semiconductor structures.

In some examples of the present disclosure, referring to FIG. 6, each source line layer 210 includes the conductive portion 211 and the insulating portion 212. The conductive portion 211 and the insulating portion 212 are located on two sides of the first contact structure 410, respectively.

In some examples of the present disclosure, referring to FIG. 7, the second contact structure 420 may include the conductive structure 421 and the insulating layer 422. The insulating layer 422 surrounds a sidewall of the conductive structure 421, and the insulating layer 422 is configured to insulate the conductive structure 421 from other semiconductor structures.

In some examples disclosed herein, referring to FIG. 7, each bit line layer 220 includes the conductive portion 221 and the insulating portion 222.

In an example of the present disclosure, referring to FIG. 5A, the memory structure 30 includes the control gate 301, the storage layer 302, the isolation layer 303, and the channel layer 304. A voltage applied to the control gate 301 may change a state of the storage layer 302, thereby implementing writing or reading of data. The storage layer 302 may be a ferroelectric storage layer or a floating gate storage layer.

In an example of the present disclosure, in conjunction with FIGS. 3 and 5A, the third contact structure 230 and the storage layer 302 of the memory structure 30 extend through the n layers of the semiconductor structures 20 along the first direction Z. The third contact structure 230 in FIG. 3 may form the control gate 301 in FIG. 5A. The storage layer 302 surrounds a sidewall of the third contact structure 230. The third contact structure 230 is connected to a word line layer (not shown in the figures). That is, the control gate 301 of the memory structure 30 is led out from the third contact structure 230 and connected to the word line layer. An outer sidewall of the storage layer 302 is covered with the isolation layer 303. The channel layer 304 is located at an intersection of the isolation layer 303 and respective one of the n layers of the semiconductor structures 20.

In an example of the present disclosure, referring to FIGS. 3 or 4, the first conductive layer 210 is connected to the first end of the memory structure 30, and the second conductive layer 220 is connected to the second end of the memory structure 30. The first end of the memory structure 30 may serve as one of a source and a drain of the memory structure 30, and the second end of the memory structure 30 may serve as the other of the source and the drain of the memory structure 30.

Based on a concept similar to the above memory device, an example of the present disclosure further provides a semiconductor structure.

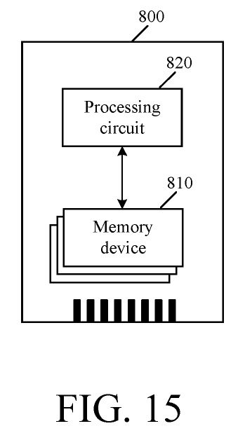

FIG. 15 is an optional schematic structural diagram of a semiconductor structure provided by an example of the present disclosure. As shown in FIG. 15, the semiconductor structure 800 includes one or more memory devices 810, and a processing circuit 820. The processing circuit 820 is coupled to the memory device 810, and is configured to control the memory device 810. The memory device 810 has technical features of the aforementioned examples, which will not be repeated here.

In an example of the present disclosure, referring to FIG. 15, the semiconductor structure 800 includes a computing-in-memory chip. The processing circuit 820 may receive data from the memory device 810 and perform an operation on the data. The processing circuit 820 may include the analog-to-digital conversion circuit and the data processing circuit in the first semiconductor structure 700 shown in FIG. 1. The memory device 810 may include the memory array 610 and the peripheral circuit 620 in the second semiconductor structure 600 shown in FIG. 1. That is to, when an operation needs to be performed on data, the processing circuit 820 may directly read data from the memory device 810 and perform the operation. In this way, the operation procedure may be completed inside the semiconductor structure 800, thereby greatly reducing delay and power consumption of data transmission and improving operation efficiency.

In an example of the present disclosure, still referring to FIG. 15, the processing circuit 820 may manage the data stored in the memory device 810 and communicate with a host. The processing circuit 820 may be configured to control operations of the memory device 810, such as read, write, and refresh operations. The processing circuit 820 may also be configured to manage various functions with respect to data stored or to be stored in the memory device 810, including but not limited to refresh and timing control, command/request conversion, buffering and scheduling, and power management. In some examples, the processing circuit 820 is further configured to determine the maximum memory capacity that a computer system may use, the number of memory banks, type and speed of memory, depth and width of memory particle data, and other important parameters. Any other suitable functions may also be performed by the processing circuit 820. The processing circuit 820 may communicate with an external device (e.g., a host) according to a particular communication protocol. For example, the processing circuit 820 may communicate with the external device through at least one of various interface protocols, such as a USB protocol, an MMC protocol, a peripheral component interconnect (PCI) protocol, a PCI express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated driver electronics (IDE) protocol, Firewire protocol, etc.

Based on the above semiconductor devices, an example of the present disclosure further provides an electronic device comprising a semiconductor device as described in any of the above examples.

Here, the specific structure of the semiconductor device refers to the above examples. Since this electronic device adopts all the technical solutions of all the above examples, it has at least all the beneficial effects brought by the technical solutions of the above examples, which will not be repeated here.

In some examples, the electronic device may also include a host, wherein the host may be a processor of an electronic device, such as a central processing unit (CPU), or a system-on-chip (SoC), such as an application processor (AP).

In some examples, the above electronic devices may be any device capable of storing data, such as a mobile phone, a desktop computer, a tablet, a laptop computer, a server, a vehicle device, a wearable device, a portable power source, etc.

It should be understood that references to “one example” or “an example” throughout the specification mean that particular features, structures, or characteristics related to the example are included in at least one example of the present disclosure. Therefore, “in one example” or “in an example” appearing throughout the specification does not necessarily refer to the same example. In addition, the particular features, structures, or characteristics may be combined in one or more examples in any suitable manner. It should be understood that in the various examples of the present disclosure, the sequence numbers of the above processes do not imply the order of execution. The order of execution of each process should be determined by its function and internal logic, and should not impose any limitation on the implementation process of the examples of the present disclosure. The above sequence numbers of the examples of the present disclosure are merely for description and do not represent the superiority or inferiority of the examples.

The above descriptions are merely preferred implementations of the present disclosure, and not intended to limit the patent scope of the present disclosure. Equivalent structure transformation made by utilizing the contents of the specification and the drawings of the present disclosure under the inventive concept of the present disclosure, or direct/indirect application to other related technical fields are both encompassed within the patent protection scope of the present disclosure.

What is claimed is:

1. A semiconductor device, comprising:
n layers of semiconductor structures, wherein n is an integer greater than 1;
memory structures arranged in an array; and
first contact structures,
wherein the n layers of semiconductor structures are stacked along a first direction, and each layer of the n layers of semiconductor structures comprises a first conductive layer and a second conductive layer that are spaced apart from each other, the first conductive layer being connected to a first end of one or more memory structures of the memory structures, the second conductive layer being connected to a second end of the one or more memory structures of the memory structures, and
wherein a first contact structure of the first contact structures extends through at least two layers of the n layers of semiconductor structures along the first direction, and a conductive structure in the first contact structure is connected to at least two first conductive layers of the at least two layers.

2. The semiconductor device of claim 1, further comprising second contact structures,
wherein a second contact structure of the second contact structures extends through at least one layer of the n layers of semiconductor structures along the first direction, and the second contact structure is connected to a corresponding second conductive layer of the at least one layer.

3. The semiconductor device of claim 2, wherein:
the first contact structure is disposed on a side of the first conductive layer or at an end of the first conductive layer, and
the second contact structure is disposed on a side of the second conductive layer or at an end of the second conductive layer.

4. The semiconductor device of claim 2, wherein:
the first contact structure is disposed between two corresponding memory structures of the memory structures, and
the second contact structure is disposed at a periphery of the memory structures.

5. The semiconductor device of claim 1, wherein:
the first conductive layer is a source line layer, and the second conductive layer is a bit line layer, or
the first conductive layer is a bit line layer, and the second conductive layer is a source line layer.

6. The semiconductor device of claim 5, wherein the source line layer is located on a side of two rows of the memory structures away from each other,
a first portion of the bit line layer is located on a side of the two rows of the memory structures facing each other, and is connected to a second end of the one or more corresponding memory structures, and
corresponding memory structures connected to the source line layer are correspondingly connected to two bit line layers, respectively.

7. The semiconductor device of claim 6, wherein:
a second portion of the bit line layer is located on a side of two rows of second contact structures away from each other, and is connected to the two rows of second contact structures,
a third portion of the bit line layer connects the first portion and the second portion of the bit line layer, and
a gap of the first portion of the bit line layer is smaller than that of the second portion of the bit line layer.

8. The semiconductor device of claim 5, wherein the source line layer comprises a conductive portion and an insulating portion, and
wherein the conductive portion and the insulating portion are respectively located on two sides of a first contact structure corresponding to the source line layer.

9. The semiconductor device of claim 1, further comprising a third contact structure ,
wherein the third contact structure and a storage layer of a corresponding memory structure of the memory structures extend through the n layers of semiconductor structures along the first direction, the storage layer of the corresponding memory structure surrounds a sidewall of the third contact structure, and the third contact structure is connected to a corresponding word line layer, and
wherein an outer sidewall of the storage layer is covered with an isolation layer of the corresponding memory structure, and a channel layer of the corresponding memory structure is at an intersection of the isolation layer and a respective one of the n layers of semiconductor structures.

10. The semiconductor device of claim 1, wherein the first contact structure comprises a conductive structure and an insulating layer, and the insulating layer surrounds a sidewall of the conductive structure.

11. A method of forming a semiconductor device, the method comprising:
providing n layers of semiconductor structures stacked along a first direction, wherein n is an integer greater than 1, wherein each layer of the n layers of semiconductor structures comprises a first conductive layer and a second conductive layer that are spaced apart from each other, the first conductive layer is connected to a first end of one or more memory structures, and the second conductive layer is connected to a second end of the one or more memory structures; and
forming m first contact structures, wherein m is an integer smaller than n and greater than or equal to 1, wherein a first contact structure of the m first contact structures extends through at least two layers of the n layers of semiconductor structures along the first direction, and a conductive structure in the first contact structure is connected to at least two first conductive layers of the at least two layers.

12. The method of claim 11, wherein forming the m first contact structures comprises:
etching a sacrificial layer and an insulating portion of the first conductive layer at a position close to a conductive portion of the first conductive layer to form m first vias, wherein a depth difference between adjacent two of the m first vias is greater than or equal to a thickness of two layers of the n layers of semiconductor structures;
forming an insulating layer on an inner wall of each first via of the m first vias, wherein the insulating layer in the first via exposes insulating portions of at least two corresponding first conductive layers located at a bottom of the first via;
etching the insulating portions of the at least two corresponding first conductive layers exposed in each of the first vias, until conductive portions of the at least two corresponding first conductive layers are exposed; and
filling a respective conductive structure in each of the first vias to form the m first contact structures.

13. The method of claim 11, further comprising:
forming n second contact structures at a position close to a conductive portion of the second conductive layer, wherein each second contact structure of the n second contact structures extends through at least one layer of the n layers of semiconductor structures along the first direction, and is connected to a corresponding second conductive layer.

14. The method of claim 11, wherein:
the first conductive layer is a source line layer, and the second conductive layer is a bit line layer, or
the first conductive layer is a bit line layer, and the second conductive layer is a source line layer.

15. A system, comprising:
a memory device comprising a memory array and a peripheral circuit; and
a processing circuit coupled to the memory device and configured to control the memory device,
wherein the memory array comprises n layers of semiconductor structures, memory structures arranged in an array, and first contact structures, wherein n is an integer greater than 1, and the n layers of semiconductor structures are stacked along a first direction,
wherein each layer of the n layers of semiconductor structures comprises a first conductive layer and a second conductive layer that are spaced apart from each other, the first conductive layer being connected to a first end of one or more memory structures of the memory structures, the second conductive layer being connected to a second end of the one or more memory structures of the memory structures, and
wherein a first contact structure of the first contact structures extends through at least two layers of the n layers of semiconductor structures along the first direction, and is connected to at least two first conductive layers of the at least two layers.

16. The system of claim 15, wherein the system comprises a computing-in-memory chip, and the processing circuit is configured to receive data from the memory device and perform an operation on the data.

17. The system of claim 15, wherein the memory array further comprises second contact structures, and
wherein a second contact structure of the second contact structures extends through at least one layer of the n layers of semiconductor structures along the first direction, and is connected to a corresponding second conductive layer of the at least one layer.

18. The system of claim 17, wherein:
the first contact structure is disposed on a side of the first conductive layer or at an end of the first conductive layer,
the second contact structure is disposed on a side of the second conductive layer or at an end of the second conductive layer, and
the memory device is configured to store weight data and output data obtained after performing an operation on the weight data.

19. The system of claim 15, wherein:
the first conductive layer is a source line layer, and the second conductive layer is a bit line layer, or
the first conductive layer is a bit line layer, and the second conductive layer is a source line layer.

20. The system of claim 19, wherein the source line layer is located on a side of two rows of the memory structures away from each other, a first portion of the bit line layer is located on a side of the two rows of the memory structures facing each other, and is connected to a second end of the one or more corresponding memory structures, and corresponding memory structures connected to the source line layer are correspondingly connected to two bit line layers, respectively, and
wherein a second portion of the bit line layer is located on a side of two rows of second contact structures away from each other, and is connected to the two rows of second contact structures, a third portion of the bit line layer connects the first portion and the second portion of the bit line layer, and a gap of the first portion of the bit line layer is smaller than that of the second portion of the bit line layer.
